(19) United States
(12) Patent Application Publication
(10) Pub. No.: US 2011/0049539 A1
(43) Pub. Date: Mar. 3, 2011

(54) Light-Emitting Diode With High Color-Rendering Index

(75) Inventors: Chih-Hung Wei, Taipei County (TW); Ming-Chang Wu, Taipei County (TW); Johnny Wu, Taipei County (TW)

(73) Assignee: HIGH POWER LIGHTING CORPORATION, Taipei (TW)

(21) Appl. No.: 12/549,356

(22) Filed: Aug. 27, 2009

(51) Int. Cl. H01L 27/15

(52) U.S. Cl. 257/89; 257/E27.121

(57) ABSTRACT

A light-emitting diode (LED) with high color-rendering index includes a substrate being provided on one face with a plurality of recesses; a plurality of first chips being separately disposed in the recesses and adapted to emit blue light; a plurality of fluorescent glues being separately filled in the recesses; at least one second chip being disposed on the substrate at a predetermined position to electrically connect to the first chips, and adapted to emit red light; and a light-transmittable layer provided on the substrate to protectively cover the first chips, the fluorescent glues, and the second chip. The blue light emitted from the first chips and the yellow or green light from the fluorescent glues are mixed first, and the produced light is then further mixed with the red light emitted from the second chip to produce warm white light, which is then projected through the light-transmittable layer.

### FIELD OF THE INVENTION

The present invention relates to a light-emitting diode (LED) with high color-rendering index, and more particularly to an LED capable of emitting warm white light by mixing light produced by first chips and fluorescent glues with light from second chips and therefore having high color-rendering index.

### BACKGROUND OF THE INVENTION

A conventional white-light light-emitting diode (LED) 6, as shown in FIG. 3, includes a printed circuit board 61 being provided with at least one recess 611; a light emitting element 62 being fixed in the recess 611; and a first colloidal material 63 being filled in the recess 611. The light emitting element 62 is adapted to emit blue light, and the first colloidal material 63 includes at least one type of yellow fluorescent powder. With these arrangements, the blue light emitted from the light emitting element 62 interacts with the yellow fluorescent powder in the first colloidal material 63 to produce desired white light.

While the above-structured white-light LED 6 emits white light by mixing the blue light from the light emitting element 62 and yellow light from the first colloidal material 63, the blue-light light emitting element 62 and the yellow-light first colloidal material 63 have relatively low color-rendering index. As a result, the white light emitted from the LED 6 is not a pure white light but a bluish-white light. Therefore, the white-light LED 6 actually fails to achieve the claimed white-light effect.

### SUMMARY OF THE INVENTION

A primary object of the present invention is to provide an LED with high color-rendering index, so as to emit warm white light.

To achieve the above and other objects, the LED according to the present invention includes a substrate being provided on one face with a plurality of recesses; a plurality of first chips being separately disposed in the recesses and adapted to emit blue light; a plurality of fluorescent glues being separately filled in the recesses; at least one second chip being disposed on the substrate at a predetermined position to electrically connect to the first chips, and adapted to emit red light; and a light-transmittable layer provided on one face of the substrate to protectively cover the first chips, the fluorescent glues, and the second chip.

The blue light emitted from the first chips and yellow or green light from the fluorescent glues are mixed first, and the produced light is then further mixed with the red light emitted from the second chip to produce warm white light, which is projected through the light-transmittable layer.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectioned top view of an LED with high color-rendering index according to a preferred embodiment of the present invention;

FIG. 2 is a sectioned side view of the LED with high color-rendering index shown in FIG. 1; and

FIG. 3 is a sectioned side view of a conventional white-light LED.

### DETAILED DESCRIPTION OF THE PREFERRED EMBODIMENTS

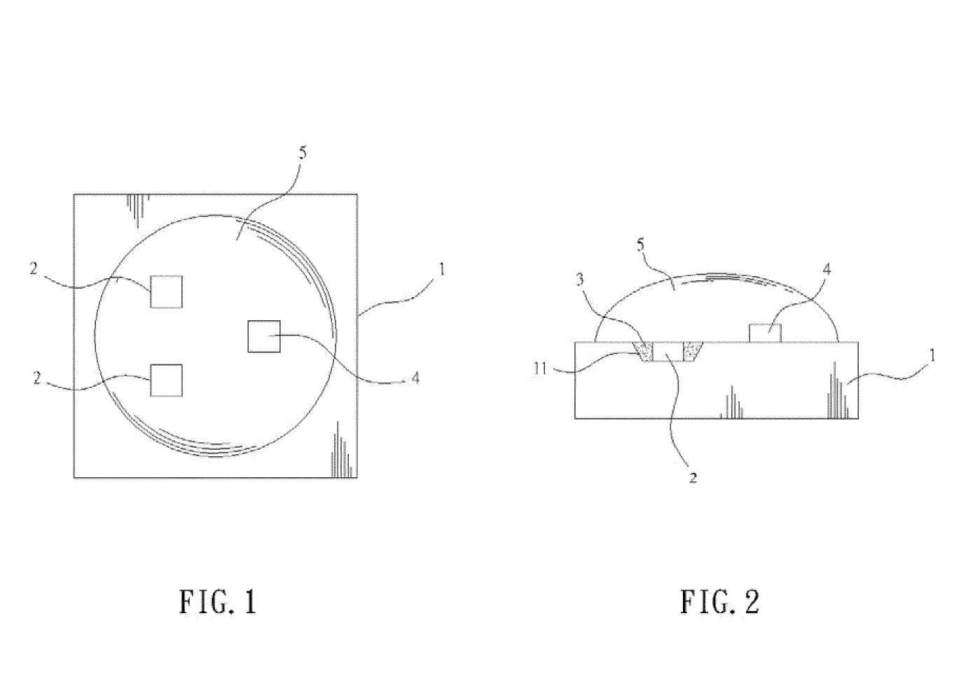

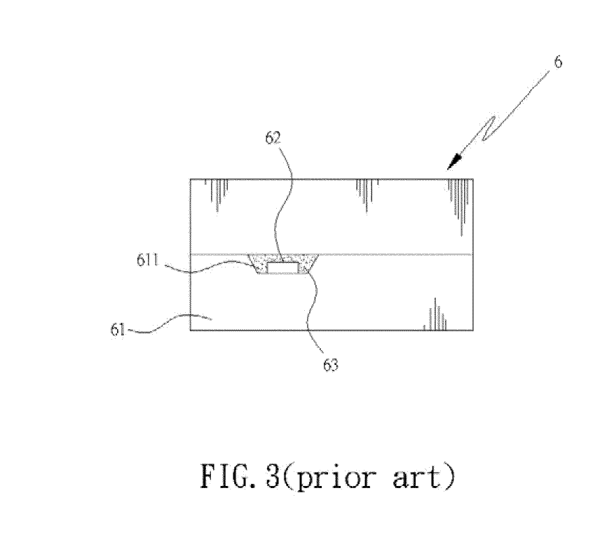

Please refer to FIGS. 1 and 2 that are sectioned top and side views, respectively, of a light-emitting diode (LED) with high color-rendering index according to a preferred embodiment of the present invention. As shown, the LED with high color-rendering index according to the present invention includes a substrate 1, a plurality of first chips 2, a plurality of fluorescent glues 3, at least one second chip 4, and a light-transmittable layer 5.

The substrate 1 is provided on one face with a plurality of recesses 11, and can be made of a heat-radiating material, such as an aluminum material, a copper material, etc.

The first chips 2 each are individually disposed in one of the plurality of recesses 11 on the substrate 1, and the first chips 2 are blue-light chips for emitting blue light.

The fluorescent glues 3 are separately filled in the recesses 11 on the substrate 1, and each include at least yellow fluorescent powder and green fluorescent powder.

The second chip 4 is disposed on the substrate 1 at a predetermined position, and electrically connected to the first chips 2. The second chip 4 is a red-light chip for emitting red light.

The light-transmittable layer 5 is provided on a top of the face of the substrate 1 with the first chips 2, the fluorescent glues 3 and the second chip 4, so as to protectively cover the first chips 2, the fluorescent glues 3, and the second chip 4. The light-transmittable layer 5 can be transparent or frosted, and can be made of a light-transmittable colloidal material, such as an epoxy resin material, a silicon colloidal material, etc. With the above arrangements, an LED with high color-rendering index according to the present invention is formed.

The LED of the present invention can be applied to relevant electronic apparatus for use on a circuit board thereof (not shown), such that when the power needed by the LED is supplied from the electronic apparatus to the LED, light can be emitted from the LED. When the LED is supplied with electric current, the first chips 2 and the second chip 4 are simultaneously caused to emit light. At this point, the blue light emitted from the first chips 2 is transmitted through the yellow or green fluorescent powder in the fluorescent glues 3 to complete a first time light mixture, and the light produced from the first mixing of lights is further mixed with the red light emitted from the second chip 4. In this manner, the LED can have high color-rendering index to emit warm white light, which is then projected through the light-transmittable layer 5.

In brief, in the LED according to the present invention, since the light produced by mixing the blue light emitted from the first chips and the yellow or green light from the fluorescent glues is further mixed with the red light emitted from the second chip, the LED can have high color-rendering index and a warm white light can be produced and transmitted through the light-transmittable layer, making the LED of the present invention improved and practical for use to meet users' demands.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A light-emitting diode (LED) with high color-rendering index, comprising:
a substrate being provided on one face with a plurality of recesses;
a plurality of first chips being separately disposed in the recesses, and the first chips being able to emit blue light;
a plurality of fluorescent glues being separately filled in the recesses;
at least one second chip being disposed on the substrate at a predetermined position to electrically connect to the first chips, and the second chip being able to emit red light; and
a light-transmittable layer being provided atop the face of the substrate with the first chip, the fluorescent glues, and the second chip disposed thereon, so as to protectively cover the first chip, the fluorescent glues, and the second chip.

2. The LED with high color-rendering index as claimed in claim 1, wherein the substrate is made of a heat-radiating material selected from the group consisting of at least an aluminum material and a copper material.

3. The LED with high color-rendering index as claimed in claim 1, wherein the fluorescent glues include at least yellow fluorescent powder and green fluorescent powder.

4. The LED with high color-rendering index as claimed in claim 1, wherein the light-transmittable layer is selected from the group consisting of a light-transmittable transparent layer and a light-transmittable frosted layer.

5. The LED with high color-rendering index as claimed in claim 1, wherein the light-transmittable layer is made of a light transmittable colloidal material selected from the group consisting of an epoxy resin material and a silicon colloidal material.
